(19) United States
(12) Patent Application Publication
(10) Pub. No.: US 2014/0246076 A1
(43) Pub. Date: Sep. 4, 2014

(54) Thermal Device with Light Guide

(71) Applicants: Eric Pilat, Brison-Saint-Innocent (FR); Mickael Albaric, La Montte-Servolex (FR)

(72) Inventors: Eric Pilat, Brison-Saint-Innocent (FR); Mickael Albaric, La Montte-Servolex (FR)

(73) Assignee: Commissariat a L'Energie Atomique et aux Energies Alternatives, Paris (FR)

(21) Appl. No.: 14/342,906

(22) PCT Filed: Sep. 5, 2012
(86) PCT No.: PCT/EP2012/067265

§ 371 Date: May 15, 2014

(30) Foreign Application Priority Data
Sep. 5, 2011 (FR) 1157834

(51) Int. Cl. F24J 2/06; H01L 31/0525; F24J 2/24

(52) U.S. Cl. CPC F24J 2/062; F24J 2/242; H01L 31/058
USPC 136/248; 126/663; 126/698; 29/890.033

(57) ABSTRACT

Thermal device comprising a thermal part (20) comprising a multitude of heat-transfer tubes (21) for the passage of a heat-transfer fluid, characterized in that it comprises a light guide (10) placed above the thermal part (20), this light guide (10) having an optical property allowing an incident light ray to be guided in various exit directions depending or the angle of incidence of the incident light ray, so as to orient most of the incident light onto the heat-transfer tubes (21) at low incidence, such as in winter, and to beside these heat-transfer tubes (21) at high incidence, such as in summer.

The invention relates to a solar device, such as a thermal module for example. It also relates to a process for manufacturing such a thermal device.

The principle behind a thermal module is the exploitation of solar radation to produce hot water, which is used by a heating system of a building and/or to produce its sanitary hot water, The need for the hot water produced by a thermal module is highly dependent on season. Specifically, the need is great in winter, especially for heating, and much less great in summer. A drawback of existing thermal devices comprising thermal modules is that they accumulate too much energy in summer, which may lead to heat being stored unnecessarily, thereby in particular leading the device to overheat, which runs the risk of it degrading because of the large increase in its temperature.

Thus, there is a need for a solution allowing the aforementioned drawback to be remedied.

For this purpose, the invention relates to a thermal device comprising a thermal part comprising a multitude of heat-transfer tubes for the passage of a heat-transfer fluid, noteworthy in that it comprises a light guide placed above the thermal part, this light guide having an optical property allowing an incident light ray to be guided in various directions depending on the angle of incidence of the incident light ray, so as to orient most of the incident light onto the heat-transfer tubes at low incidence, such as in winter, and to beside these heat-transfer tubes at high, incidence, such as in summer.

The invention is more precisely defined by the claims.

These objects, features and advantages of the present invention will be explained in more detail in the following description of particular embodiments, given by way of nonlimiting example and with regard to the appended figures in which:

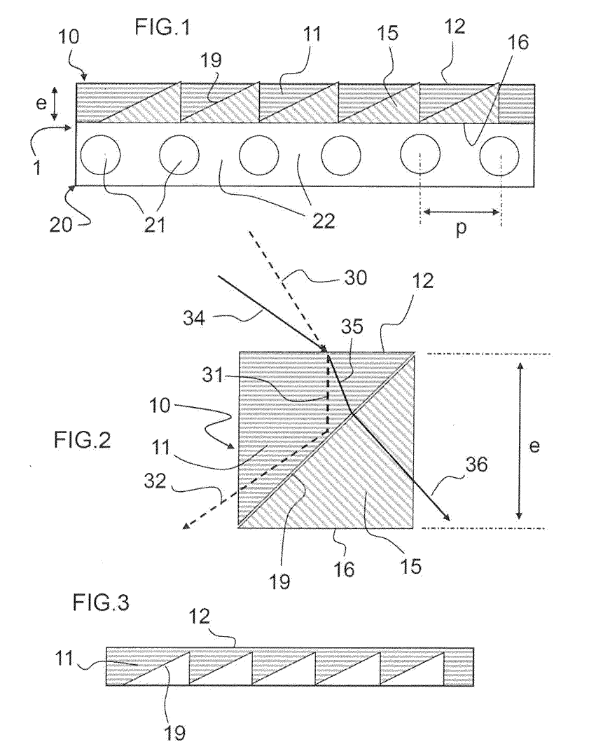

FIG. 1 schematically shows a thermal module according to one embodiment of the invention.

FIG. 2 shows an enlargement of a part of the light guide of the thermal module according to the embodiment of the invention.

FIG. 3 schematically shows a light guide according to a first variant.

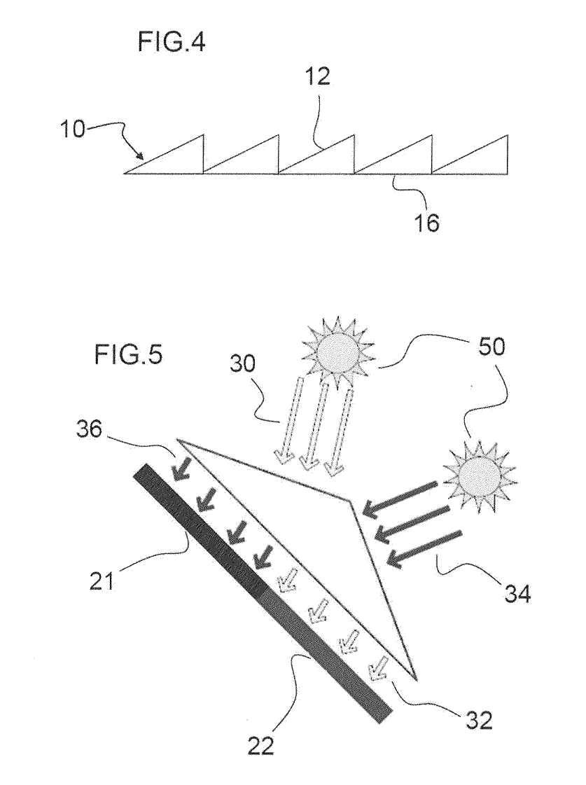

FIG. 4 schematically shows a light guide according to a second variant.

FIG. 5 schematically shows the operation of the light guide in this second variant by way of an enlargement of one part of the light guide.

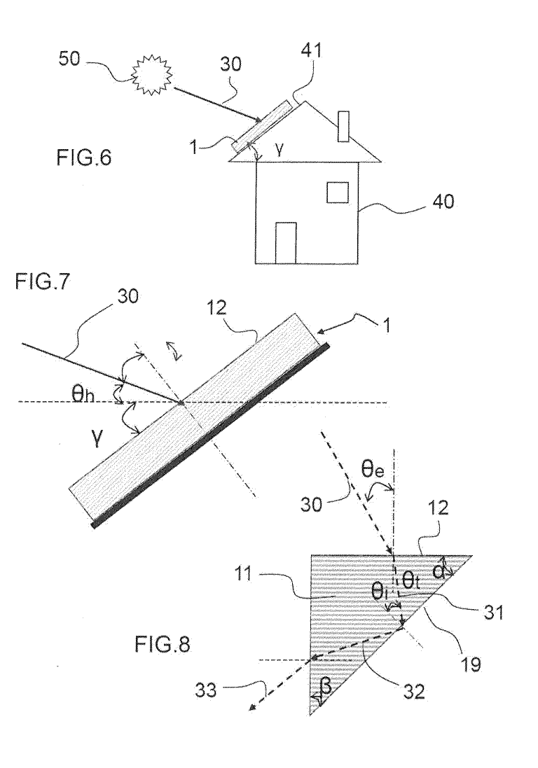

FIG. 6 schematically shows the implementation on a building of a thermal module according to the embodiment of the invention.

FIGS. 7 and 8 show enlargements of one part of the light guide of the thermal module according to the embodiment of the invention in its implementation in FIG. 5.

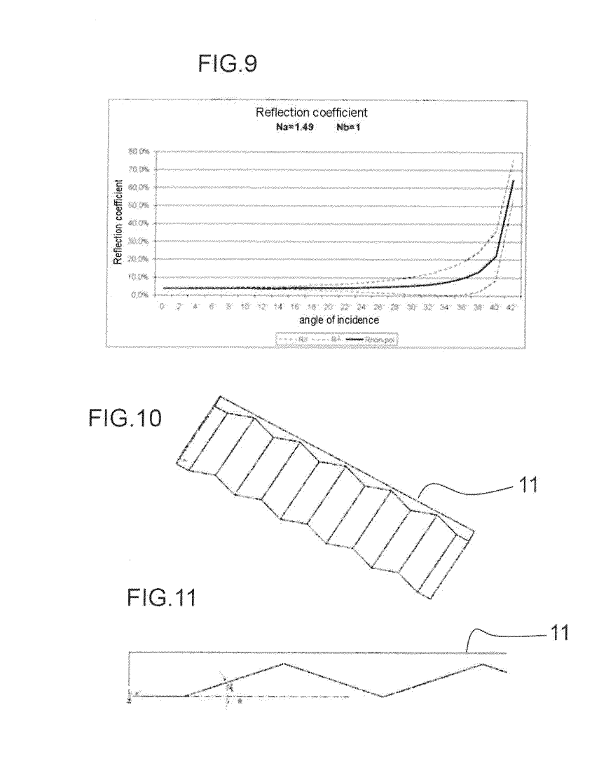

FIG. 9 shows the variation of the reflection coefficient of the light guide according to one embodiment of the invention as a function of the angle of incidence of a light ray.

FIG. 10 schematically shows, in perspective, a toothed component of the light guide according to one embodiment of the invention.

FIG. 11 schematically shows a side view of the toothed component of the light guide according to the embodiment of the invention.

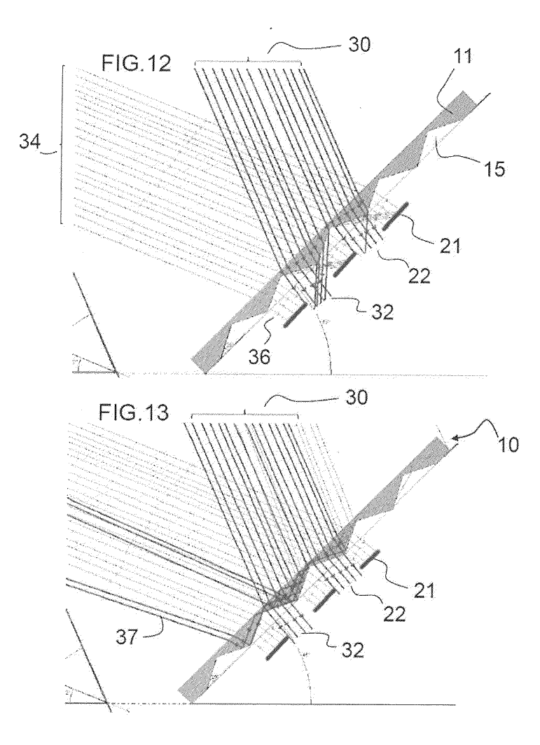

FIG. 12 schematically shows the operation of the light guide according to one embodiment of the invention.

FIG. 13 schematically shows the operation of a variant of the light guide according to one embodiment of the invention.

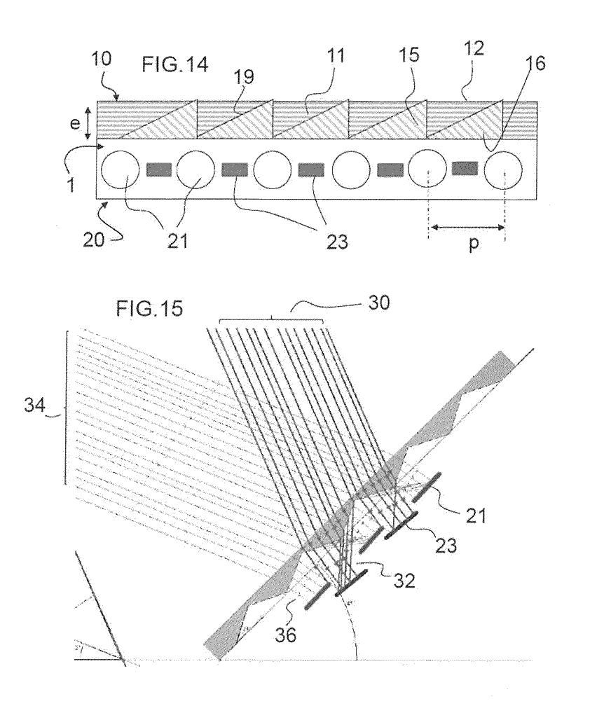

FIG. 14 schematically shows a hybrid thermal module according to one embodiment of the invention.

FIG. 15 schematically shows the operation of the hybrid thermal module according to the embodiment of the invention.

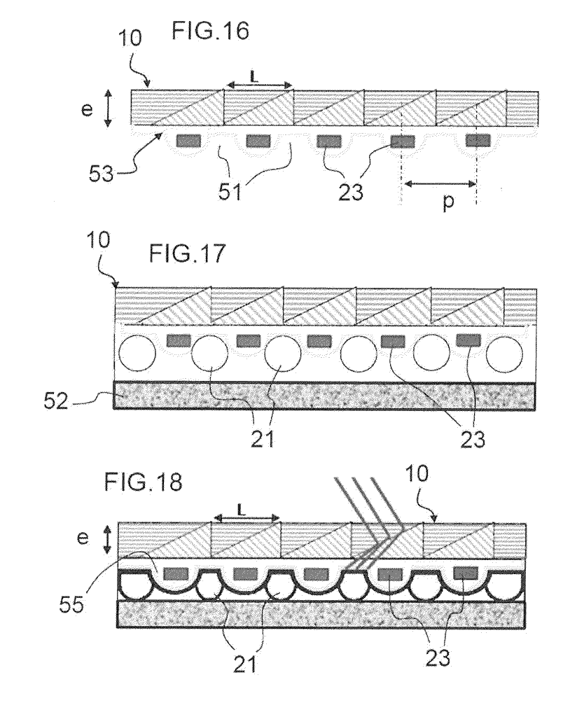

FIGS. 16 to 18 show various steps of processes for manufacturing a hybrid thermal module according to one embodiment of the invention.

In the following description, the same references will be used for similar elements in the various figures, for the sake of simplifying comprehension.

The embodiments of the invention that will be described are used on the use of a light guide, which allows light rays exiting the light guide to be guided in order to direct them differently depending on their angle of incidence, and especially orient them differently when the angle of incidence is low, for example in winter, and when the angle of incidence is higher, for example in summer, thereby taking advantage of seasonal variations in the height of the sun. Thus, this light guide functions as an automatic season-dependent switch, allowing light rays to be switched from one zone to another of a solar device, while simultaneously ensuring the solar device has a minimal bulk.

Thus, FIG. 1 shows a thermal module 1 according to one embodiment of the invention. The upper part of this thermal module comprises a light guide 10 forming a cover of the module. Under this light guide, the module comprises a thermal part 20 comprising parallel heat-transfer tubes 21 that are distributed with a constant pitch p smaller than or equal to 50 mm, and that are separated by spaces 22.

The light guide 10 is formed from two superposed materials with different optical properties. An upper component 11, comprising the first material, forms the fiat upper surface 12 of the light guide, via which the incident light rays arrive. A lower component 15, comprising the second material, forms the flat lower surface 16 of the light guide, via which the light rays exit, after having passed through the light guide 10, in the direction of the chosen zones of the thermal part 20. In this embodiment, the two materials are stiff and transparent, translucent or semitransparent, and, for example, are plastics, such as PMMA, with different refractive indices. In addition, these two materials comprise a surface inside the light guide, which surface has a toothed shape. Their toothed shapes are complementary so as to form a continuous internal joining surface 19 between the two components 11, 15 of the light guide, which remain in contact over all of this joining surface 19. It will be noted that the shape of each tooth is composed of a portion that is perpendicular to the upper and lower flat parallel surfaces 12 and 16, and an oblique portion. In addition, the pitch of these teeth is the same pitch p as that of the heat-transfer tubes 21 of the lower thermal part 20, in order to obtain an effect that will be described below.

By way of example, FIG. 2 illustrates the path of two light rays within the light guide 10. A first incident ray 30, having an angle of incidence corresponding, for example, to a summertime situation, is refracted into a refracted ray 31 within the first component 11 of the light guide, on arriving at the upper surface 12 of the light guide. Next, this refracted ray 31 arrives at the oblique joining surface 19 between the two components 11, 15 of the light guide, at an angle such that it is reflected in order, finally, to generate, on exiting the light guide, an output ray 32 that is oriented in a first direction. A second incident ray 34, having a low angle of incidence, corresponding, for example, to a wintertime situation, is refracted into a refracted ray 35 within the first component 11 of the light guide, on arriving at the upper surface 12 of the light guide. Next, this refracted ray 35 arrives at the joining surface 19 between the two components 11, 15 of the light guide, so as to generate a new refracted ray 36 within the second component, which ray 36 then exits from under the light guide, in a second direction. Thus, it indeed appears that the light guide 10 differently orients the light rays exiting its lower side 16 depending on their angle of incidence, and therefore on the season.

It will be noted that variants of such a light guide may be employed. In this respect, FIG. 3 illustrates a first variant of a light guide 10 in which the second component 15 is removed and replaced by a space filled with a gas, such as air or nitrogen for example, which acts as the second material with different optical properties, in a way equivalent to the operation described with regard to FIG. 2.

The light guides according to the embodiments described above have the advantage of having a flat upper surface 12, thereby enabling them to be cleaned by rain, preventing the accumulation of dust inter alia. However, FIG. 4 shows a second variant in which the light guide 20 comprises only a single component 11 and has an upper surface 12 with reliefs, for example teeth, so as to orient the light rays differently depending on their angle of incidence.

FIG. 5 schematically illustrates the operation of such a variant with a single tooth for the sake of simplicity, which alternatively receives incident rays 30 corresponding to a summer season and lower incident rays 34 that correspond, for example, to the winter season, according to the position of the sun 50. These incident rays 30, 34 of different angles of incidence strike two separate surfaces of the tooth of the light guide 10, which leads to rays, 32 and 36, respectively, being output from the light guide 10, which rays illuminate two separate zones, respectively. The zone illuminated in winter will naturally be chosen to correspond to that in which the heat-transfer tubes 21 are located.

FIG. 6 shows an implementation of a thermal device such as described above with reference to FIGS. 1 to 3 on the roof 41 of a building 40, for providing hot water to this dwelling. The roof has a slope γ with respect to the horizontal, thereby defining the angle of inclination of the upper surface 12 of the light guide of the thermal device, which receives a light ray 30 originating from the sun 50, more particularly shown in FIG. 7, at an angle of incidence θₙ that depends on the time of day and the season, and on the latitude of the building 40.

FIG. 8 details the path, inside the light guide, of a light ray 30 that strikes the upper surface 12 of the light guide at a certain angle θₑ to its normal. First it forms a refracted ray 31 that strikes the joining surface 19 forming the lower surface of the upper component 11 of the light guide. This lower surface is inclined at an angle a to the upper surface 12 of the light guide. This refracted ray 31 strikes this oblique surface at an angle θᵢ to its normal. Depending on the value of this angle θᵢ , the ray 31 is either refracted through this surface, or reflected into a ray 32, as shown, in order finally to provide, as output from the light guide, a ray 33 having a certain orientation that therefore depends on its angle of incidence.

As is shown in FIG. 9, the reflection coefficient of the light guide according to the variant shown in FIG. 3 depends on the angle of incidence. It would appear in the chosen example, for which the first material forming the first component 11 of the light guide has a refractive index of 1.49, whereas the second material has a refractive index of 1, that above a threshold angle of incidence of 42° all of the incident ray is reflected. This means that in FIG. 8 the refracted ray 31 is reflected if the angle θᵢ is larger than 42°.

The above considerations show that a person skilled in the art may easily determine the geometry to use for the light guide, depending on the particular implementation envisaged. Specifically, first of all the angle of incidence of solar radiation as a function of the season, especially taking into account, the slope γ of a roof 41 and the latitude L of the building 40 in question, is known (in winter the angle of incidence θₕ of a light ray with respect to the horizontal is easily estimated since its value at midday on the winter solstice is given by the expression θₕ=68−L. Likewise, it is known that at midday on the summer solstice, this angle is θₕ=112−L).

Next, all that is required is to determine the geometry of the light guide, especially its thickness e, the angle a of inclination of the toothed surface(s), and the refractive index (indices) of the material(s) used, to obtain a desired path for a light ray depending on its angle of incidence, For example, the first component 11 of this guide is shown in FIGS. 10 and 11: it turns out that its geometry may be easily defined and that it easy to manufacture by moulding, grooving with a machine tool, or extrusion of a plastic such as PMMA.

Thus, FIG. 12 shows the behaviour of a thermal device 1 such as shown in FIG. 1, the following assumptions being made:
latitude of 46° N (i.e. an angle of incidence of 66° in summer and 22° in winter);
the first component 11 is made of PMMA having a refractive index of 1.491 (in the green), the light guide taking the form of a 6 mm-thick sheet (e=6 mm) with teeth inclined, at an angle α of 29°;
the second component 15 is air, having a refractive index of 1; and
the thermal module 1 is placed with an inclination of 45°.

As may be seen in FIG. 12, in summer the outputted light rays 30 are guided so as to form transmitted rays 32 oriented toward zones 22 inserted between the various heat-transfer tubes 21, thereby allowing the latter to receive a minimum amount of heat and preventing the problem of overheating encountered in the prior art. In contrast, in winter the outputted light rays 34 are guided into light rays 36 that are specifically directed onto the heat-transfer tubes 21, in order to transmit a maximum amount of heat to them at the time of greatest need.

Naturally, the two incident light rays represent extreme situations corresponding to the summer and winter solstices at midday, and all sorts of intermediate configurations exist, depending on the time of day and the season, in which the rays outputted from the light guide are partially distributed over the heat-transfer tubes 21 and partially elsewhere. Nevertheless, as a result of the chosen configuration, the heat-transfer tubes 21 overall receive much more light in winter than in summer, which corresponds well to the effect sought. It will be noted that the pitch p of the teeth of the components 11, 15 of the light guide corresponds to the pitch at which the heat-transfer tubes 21 are distributed in order to obtain this correspondence with the outputted rays. However, other geometries are envisageable, such as geometries with inconstant pitches and/or with teeth with variable geometries, or the teeth could be replaced by simple reliefs, grooves, etc. Furthermore, it will be noted that the light guide thus described does not act to amplify the radiation and, for example, does not concentrate the rays on certain zones. All it does is modify the orientation of the rays, in order to switch them from one zone to another depending on the season. Therefore, in the chosen implementation, a first zone formed by the heat-transfer tubes 21, which is favoured in winter, is distinguished from a second zone formed by the spaces 22 between the heat-transfer tubes, which is favoured in summer, These two zones are composed of a multitude of parallel interpenetrating strips.

The above implementation of a thermal device will also possibly be different. However, this thermal device will advantageously take the form of one or more modules called panels having an inclination of 20 to 60°, even 30 to 45°, with respect to the horizontal. In addition, each thermal module will advantageously comprise a light guide containing a material with a refractive index comprised between 1.2 and 1.8, even between, 1.4 and 1.7 inclusive. A thermal module will advantageously be less than 10 mm in thickness, even less than or equal to 6 mm in thickness, which represents about 10% of the thickness of the complete device.

FIG. 13 shows the behaviour of a thermal device that has been slightly modified by replacing the first material with a material with a refractive index of 1.6 in the green). It will be noted that this device behaves differently because some of the incident rays are reflected by the light guide 10. Reflected rays 37 are seen, for example, to originate from incident rays 30 in the summer. Such a variant is advantageous when used on a curtain wall of a building for example, in order to reduce, in summer, the amount of light and therefore heat entering the building.

The invention described above makes advantageous implementation of hybrid solar devices possible.

In this respect, FIG. 14 shows a hybrid thermal module that comprises the elements described above with regard to FIG. 1, and that, in addition, comprises photovoltaic cells 23 placed between the heat-transfer tubes 21. Thus, this device allows solar radiation that is not exploited in summer to be used to produce electricity. FIG. 15 shows the operation of such a hybrid module, the same assumptions as those applied to FIG. 12 being reused. In the summer, the outputted light rays 32 are guided onto the photovoltaic cells 23 whereas, in winter, they are directed onto the heat-transfer tubes 21.

According to one advantageous embodiment, the thermal module has a very small thickness, in order to make its integration easier. This thickness firstly depends on the dimensions of the light guide, the thickness e of which must therefore be as small as possible. However, in order to fulfil its optical function, as described above, the base L of its prism-like elements, which corresponds to the pitches p of the photovoltaic cells 23 and of the heat-transfer tubes 21, must be substantially equal to its thickness e.

Thus, the choice of a very small thickness e necessitates a very small pitch p, substantially equal to e.

The standard diameter of a heat-transfer tube is 14 mm and the conventional width of photovoltaic cells is about 156 mm. A process for manufacturing a hybrid thermal module, which allows a very small thickness to be obtained, significantly smaller than if elements of these standard dimensions were used, will now be described.

According to a first embodiment, the process for manufacturing a thermal module starts with the manufacture of photovoltaic cells that are adapted to the hybrid module. This process comprises the following steps:
in a first step, photovoltaic cells 23 are cut into strips adapted to the desired width, i.e. about 10 mm according to a chosen example. This cutting is for example carried out with a laser or a cutting system based on a diamond saw;
in a second step, the photovoltaic cells 23 are cut and connected together, for example by soldering, in order to form a string of length equal to that of the thermal module;
in a third step, the light guide 10 and the photovoltaic cells 23 are covered using a resin binder 53 such as an EVA or silicone binder. This step also involves creating locations 51 dedicated to the heat-transfer tubes 21, for the thermal function of the thermal module. The result obtained after this step is illustrated in FIG. 16; and
in a fourth step, the thermal part is added to the thermal module formed beforehand. This thermal part comprises the heat-transfer tubes 21, which may take the form of a tubular network arranged in a comb or serpentine. This thermal part may, as a variant, be obtained by high-pressure blow moulding (roll-bond), this embodiment allowing the exchange surface to be adjusted depending on the optical system.

Optionally, a polymer laminate (made of TPT for example) is added to form a back face 52. The result obtained after this step is illustrated in FIG. 17.

According to a second embodiment, the thermal part may be produced first, in a high-pressure blow moulding step. This thermal part forms locations 55 for positioning the photovoltaic cells 23. Lastly, a subsequent step consists in placing the light guide 10 on top of the thermal module, which may be joined using any mechanical mechanism or by adhesive bonding using an adhesive to form a joint between the light guide and the photovoltaic cells.

This process allows thermal modules with heat-transfer tubes that are smaller than or equal to 12 mm in diameter, even smaller than or equal to 10 mm in diameter, for example about 8 mm in diameter, and/or photovoltaic cells that are smaller than or equal to 12 mm in width, for example about 10 mm in width, to be obtained.

This principle may be exploited to form other hybrid solar devices, such as, for example, a device combining a screen or blind that is semitransparent to the light and that blocks or allows the light to pass, and photovoltaic electricity production. Specifically, it may be chosen to allow a maximum amount of light to pass through the device in winter, in order to obtain maximum illumination of a building, thus providing a skylight function for example, and to prevent or limit penetration of light into the building in the summer, in order to prevent heating of the building, while simultaneously orienting this light onto photovoltaic cells. In such a variant, the solar device has an architecture similar to that shown in FIG. 14, the heat-transfer tubes 21 being replaced with transparent spaces. In such an implementation, the light guide thus allows a semitransparent device to be formed, the transparency of which varies as a function of the orientation of the incident light rays, and therefore as a function of time, and especially of the season.

It will be noted that the steps of the manufacturing processes described above advantageously allow a hybrid thermal module to be obtained. Naturally, it is possible to use just some of these steps to manufacture a simple thermal module, such as that shown in FIGS. 1 to 3, for example.

1. Thermal device comprising a thermal part (20) comprising a multitude of heat-transfer tubes (21) for the passage of a heat-transfer fluid, characterized in that it comprises a light guide (10) placed above the thermal part (20), this light guide (10) having an optical property allowing an incident light ray to be guided in various exit directions depending on the angle of incidence of the incident light ray, so as to orient most of the incident light onto the heat-transfer tubes (21) at low incidence, such as in winter, and to beside these heat-transfer tubes (21) at high incidence, such as in summer.

2. Thermal device according to the preceding claim characterized in that the light guide (10) comprises at least one component (11; 15) comprising a toothed surface.

3. Thermal device according to one of the preceding claims, characterized in that the light guide (10) comprises a flat upper surface (12) intended to receive the incident light.

4. Thermal device according to one of the preceding claims, characterized in that the light guide comprises two components (11, 15) comprising two materials with different optical properties, especially different refractive indices.

5. Thermal device according to the preceding claim, characterized in that the two components (11, 15) of the light guide each comprise complementary toothed surfaces that interfit with each other at a joining surface (19).

6. Thermal device according to one of the preceding claims, characterized in that the heat-transfer tubes (21) lie substantially parallel and are spaced apart at a constant pitch (p), and in that the light guide (10) comprises a toothed surface of the same pitch.

7. Thermal device according to one of the preceding claims, characterized in that the light guide comprises at least one component made of a plastic, such as PMMA, and/or in that it comprises at least one material having a refractive index comprised between 1.2 and 1.8, and/or in that its thickness (e) is between 5 and 10 mm.

8. Thermal device according to one of the preceding claims, characterized in that it comprises photovoltaic cells (23) inserted between the heat transfer tubes (21), so that the light is mainly oriented onto the heat-transfer tubes (21) at low incidence and onto the photovoltaic cells (23) at high incidence.

9. Thermal device according to the preceding claim, characterized in that the heat-transfer tubes (21) are smaller than or equal to 12 mm in diameter, or smaller than or equal to 10 mm in diameter, and/or in that the photovoltaic cells (23) are smaller than or equal to 12 mm in width.

10. Device that, blocks or allows incident light to pass, comprising a part (20) comprising a multitude of photovoltaic cells separated by transparent or translucent spaces, characterized in that it comprises a light guide (10) placed above said part (20), having an optical property allowing an incident light ray to be guided in various exit directions depending on the angle of incidence of the incident light ray, so as to orient most of the incident light onto the photovoltaic cells at high incidence, and to beside these photovoltaic cells, onto the transparent parts, at low incidence, in order to provide additional illumination to a zone such as a dwelling window placed behind the blocking device,

11. Process for manufacturing a thermal device according to one of claims 1 to 9, characterized in that it comprises a step of manufacturing a thermal part that comprises heat-transfer tubes (21), of the type taking the form of a tubular network arranged in a comb or serpentine, or of producing this thermal part in a high-pressure blow moulding step, then a step of fixing a light guide (10) on top of the thermal part.

12. Process for manufacturing a thermal device according to the preceding claim, characterized in that the thermal device is a hybrid device, and in that it comprises the following steps:
cutting photovoltaic cells (23) into strips;
connecting photovoltaic cells (23) together in order to form a s ring of length equal to that of the thermal module; and
creating locations (51) for receiving heat-transfer tubes (21) of a thermal part, or creating locations (55) on the thermal part for receiving the photovoltaic cells (23).
